(19) United States
(12) Patent Application Publication
(10) Pub. No.: US 2009/0181537 A1
(43) Pub. Date: Jul. 16, 2009

(54) SEMICONDUCTOR STRUCTURE COMPRISING AN ELECTRICAL CONNECTION AND METHOD OF FORMING THE SAME

(75) Inventors: ROBERT SEIDEL, Dresden (DE); Ralf Richter, Dresden (DE); Frank Feustel, Dresden (DE)

Correspondence Address: Mark W. Sincell;WILLIAMS, MORGAN & AMERSON, P.C., Suite 1100, 10333 Richmond, Houston, TX, 77042, US

(73) Assignee: ADVANCED MICRO DEVICES, INC.

(21) Appl. No.: 12/411,873

(22) Filed: Mar. 26, 2009

Related U.S. Application Data
(62) Division of application No. 11/943,820, filed on Nov. 21, 2007.

(30) Foreign Application Priority Data
Apr. 30, 2007 (DE) 10 2007 020 269.7

(51) Int. Cl. H01L 21/768

(52) U.S. Cl. 438/672; 438/697; 257/E21.585

(57) ABSTRACT

A method of forming a semiconductor structure comprises providing a substrate comprising a layer of a first material. A protection layer is formed over the layer of first material. At least one opening is formed in the layer of first material and the protection layer. A layer of a second material is formed over the layer of first material and the protection layer to fill the opening with the second material. A planarization process is performed to remove portions of the layer of second material outside the opening. At least a portion of the protection layer is not removed during the planarization process. An etching process is performed to remove the portions of the protection layer which were not removed during the planarization process.

### BACKGROUND OF THE INVENTION

1. Field of the Invention

The subject matter disclosed herein generally relates to the formation of integrated circuits, and, more particularly, to the formation of semiconductor structures comprising electrically conductive features stacked in a plurality of interconnect levels.

2. Description of the Related Art

Integrated circuits comprise a large number of individual circuit elements, such as transistors, capacitors and resistors. These elements are connected internally by means of electrically conductive lines to form complex circuits, such as memory devices, logic devices and microprocessors. The performance of integrated circuits may be improved by increasing the number of functional elements per circuit in order to increase their functionality and/or by increasing the speed of operation of the circuit elements. A reduction of feature sizes allows the formation of a greater number of circuit elements on the same area, hence allowing an extension of the functionality of the circuit, and also reduces signal propagation delays, thus making an increase of the speed of operation of circuit elements possible.

In modern integrated circuits, electrically conductive lines connecting circuit elements may be provided in a plurality of interconnect levels which are provided above the circuit elements and which may be stacked on top of each other. Thus, a substrate area consumed by the electrically conductive lines may be reduced. At integration densities used in advanced integrated circuits, the maximum possible speed of operation of the circuit may be limited by RC propagation delays caused by the capacitance between adjacent electrically conductive lines. In order to reduce RC propagation delays, it has been proposed to form the electrically conductive lines in layers of a dielectric material having a low dielectric constant. In particular, it has been proposed to use ultra low-k materials having a dielectric constant of less than about 2.4.

In the following, a method of forming an electrically conductive line according to the state of the art will be described with reference to FIGS. 1a-1c. FIG. 1a shows a schematic cross-sectional view of a semiconductor structure 100 in a first stage of a method of forming a semiconductor structure according to the state of the art.

The semiconductor structure 100 comprises a semiconductor substrate 101. In some examples of manufacturing methods according to the state of the art, the substrate 101 may comprise silicon. Additionally, in the substrate 101, circuit elements such as transistors, capacitors and/or resistors, as well as electrically conductive lines in deeper interconnect levels, may be formed by means of techniques well known to persons skilled in the art. On the substrate 101, a layer 102 comprising a dielectric material may be formed by means of known deposition techniques. The dielectric material of the layer 102 may be an ultra low-k material having a dielectric constant of less than about 2.4, for example, an organo-silicate glass or a spin-on glass.

A trench 103 is formed in the layer 102. A diffusion barrier layer 104 and a trench fill 105 are formed in the trench 103. The trench fill 105 may comprise an electrically conductive material such as, for example, copper. The trench 103, the diffusion barrier layer 104 and the trench fill 105 may be formed by means of known techniques of photolithography, etching, deposition and planarization, which will be explained in more detail below. The trench 103 filled with the diffusion barrier layer 104 and the trench fill 105 may provide an electrically conductive line which may be employed to electrically connect circuit elements in the substrate 102.

A layer 106 of a dielectric material, which may, for example, comprise an ultra low-k material, may be formed over the semiconductor structure 100. For this purpose, known techniques of deposition such as, for example, spin coating, chemical vapor deposition (CVD) and/or plasma enhanced chemical vapor deposition (PECVD) may be employed.

FIG. 1b shows a schematic cross-sectional view of the semiconductor structure 100 in a later stage of the manufacturing method according to the state of the art. A trench 107 and a contact via 108 are formed in the layer 106 of dielectric material. This may be done by means of known techniques of photolithography. While, in some examples of manufacturing methods according to the state of the art, the trench 107 may be formed after the formation of the contact via 108, in other embodiments, the contact via 108 may be formed after the formation of the trench 107.

After the formation of the contact via 108 and the trench 107, a diffusion barrier layer 109, which may, for example, comprise tantalum or tantalum nitride, may be formed over the semiconductor structure 100 by means of well-known deposition techniques, such as CVD and/or PECVD. Subsequently, a layer 110 of an electrically conductive material, for example, copper, may be formed over the semiconductor structure 100.

The layer 110 may be formed by means of known techniques of electroplating. For this purpose, first, a seed layer of the electrically conductive material may be formed by means of sputtering and/or electroless deposition. Thereafter, the semiconductor structure 100 may be inserted into an electrolyte comprising ions of the electrically conductive material. An electric current is applied between the semiconductor structure 100 and an electrode of the electrically conductive material. Thus, at the semiconductor structure 100, ions of the electrically conductive material are discharged and form the layer 110.

FIG. 1c shows a schematic cross-sectional view of the semiconductor structure 100 in a later stage of the manufacturing method. After the formation of the diffusion barrier layer 109 and the layer 110 of electrically conductive material, a planarization process may be performed to remove portions of the diffusion barrier layer 109 and the layer 110 outside the trench 107 and the contact via 108. The planarization process may be a chemical mechanical polishing process. As persons skilled in the art know, in chemical mechanical polishing, the semiconductor structure 100 is moved relative to a polishing pad. A slurry comprising chemical compounds adapted to react with materials of the semiconductor structure 100, in particular with the materials of the layer 110 of electrically conductive material and the diffusion barrier layer 109, is supplied to an interface between the polishing pad and the semiconductor structure 100. Reaction products are removed by abrasives contained in the slurry and/or the polishing pad.

A problem of the manufacturing method described above is that the layer 106 of dielectric material, when comprising an ultra low-k material, may have a relatively low module of elasticity and may be relatively soft. This may lead to a relatively low mechanical stability of the layer 106. In chemical mechanical polishing, friction occurring while the semiconductor structure 100 is moved over the polishing pad may create mechanical forces in the layer 106, which, due to the relatively low mechanical stability of the layer 106, may damage the layer 106, as schematically shown in FIG. 1c in a portion of the surface of the layer 106 indicated by reference numeral 111.

A further problem of the manufacturing method according to the state of the art described above is that even the relatively low dielectric constant of ultra low-k materials may lead to significant RC propagation delays, in particular in case of a plurality of trenches having a relatively low distance from each other and in case of a high frequency of operation.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to one illustrative embodiment, a method of forming a semiconductor structure is disclosed. The method involves providing a substrate comprising a layer of a first material, forming a protection layer over the layer of first material, wherein at least one opening is formed in the layer of first material and the protection layer, and forming a layer of a second material over the layer of first material and the protection layer to fill the opening with the second material. A planarization process is performed to remove portions of the layer of second material outside the opening. At least a portion of the protection layer is not removed during the planarization process. An etching process is performed to remove the portion of the protection layer which was not removed during the planarization process.

Another illustrative method of forming a semiconductor structure involves providing a substrate comprising a layer of a first material, forming a protection layer over the layer of first material and forming a first trench and a second trench in the protection layer and the layer of first material. The first trench and the second trench are adjacent each other. The first trench and the second trench are filled with a second material. An etching process is performed to remove the protection layer. The etching process is adapted to leave the second material substantially intact such that a first protrusion comprising the second material is formed over the first trench and a second protrusion comprising the second material is formed over the second trench. A deposition process is performed to form a layer of a third material over the substrate. The deposition process is adapted to form a void between the first protrusion and the second protrusion.

According to another illustrative aspect, a novel semiconductor structure is disclosed. The structure comprises a first layer of dielectric material formed over a semiconductor substrate, a first electrically conductive feature and a second electrically conductive feature. The first and the second electrically conductive features are formed adjacent each other. The first and the second electrically conductive features are formed in the first layer of dielectric material and protrude out of the first layer of dielectric material. A second layer of dielectric material is formed over the first layer of dielectric material and the first and the second electrically conductive feature. The second layer of dielectric material comprises a void located between the first electrically conductive feature and the second electrically conductive feature.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c show schematic cross-sectional views of a semiconductor structure in stages of a method of forming a semiconductor structure according to the state of the art;

FIGS. 2a-2e show schematic cross-sectional views of a semiconductor structure in stages of a method of forming a semiconductor structure according to one illustrative embodiment disclosed herein; and

FIGS. 3a-3b show schematic cross-sectional views of a semiconductor structure in stages of a method of forming a semiconductor structure according to another illustrative embodiment disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

According to one embodiment, a protection layer is formed over a layer of first material wherein a feature comprising a second material is to be formed. The protection layer may comprise a material which is harder than the first material. For example, in some embodiments, the first material may be an ultra low-k material and the protection layer may comprise silicon dioxide, silicon nitride and/or silicon oxynitride.

Thereafter, at least one opening, which may, for example, comprise a trench and/or a contact via, may be formed in the layer of first material and the protection layer. The opening may be filled with a layer of a second material which may, in some embodiments, comprise copper, and a chemical mechanical polishing process may be performed to remove portions of the layer of second material outside the opening.

During the chemical mechanical polishing process, the protection layer may substantially prevent a contact between the layer of first material and the slurry and/or the polishing pad. Due to the greater hardness of the protection layer, the protection layer may protect the layer of first material from being damaged during the course of the chemical mechanical polishing process. Thus, mechanical damages of the layer of first material may be advantageously avoided.

After the chemical mechanical polishing process, portions of the protection layer which were not removed during the chemical mechanical polishing process may be removed by means of an etch process adapted to selectively remove the material of the protection layer, leaving the first and the second material substantially intact.

In some embodiments, the at least one opening may comprise a first trench and a second trench which are formed adjacent each other. After the etch process performed in order to remove the protection layer, the second material in the first and the second trench may protrude out of the layer of first material. In such embodiments, after the removal of the protection layer, a deposition process adapted to form a layer of a third material over the substrate may be performed. The deposition process may be adapted such that a void is formed between the portions of the second material protruding out of the layer of first material. The void may have an even smaller dielectric constant than ultra low-k materials. Thus, the formation of the void may lead to an effective reduction of the k-value between the first and the second trench, which may entail a decrease of the capacitance between the first trench and the second trench. Advantageously, this may help reduce RC propagation delays.

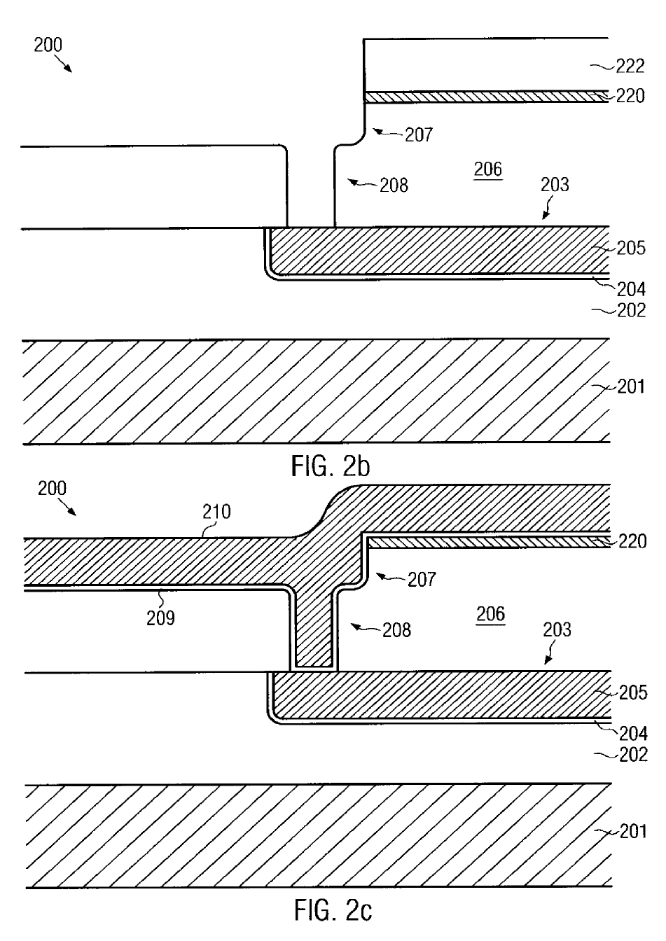

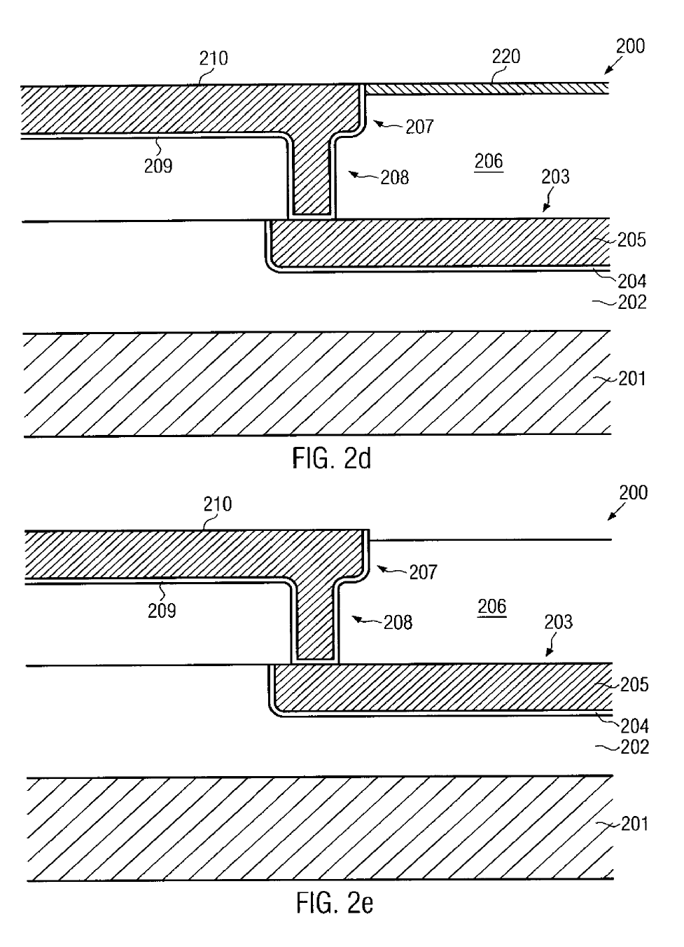

FIG. 2a shows a schematic cross-sectional view of a semiconductor structure 200 in a first stage of a method of forming a semiconductor structure according to one illustrative embodiment.

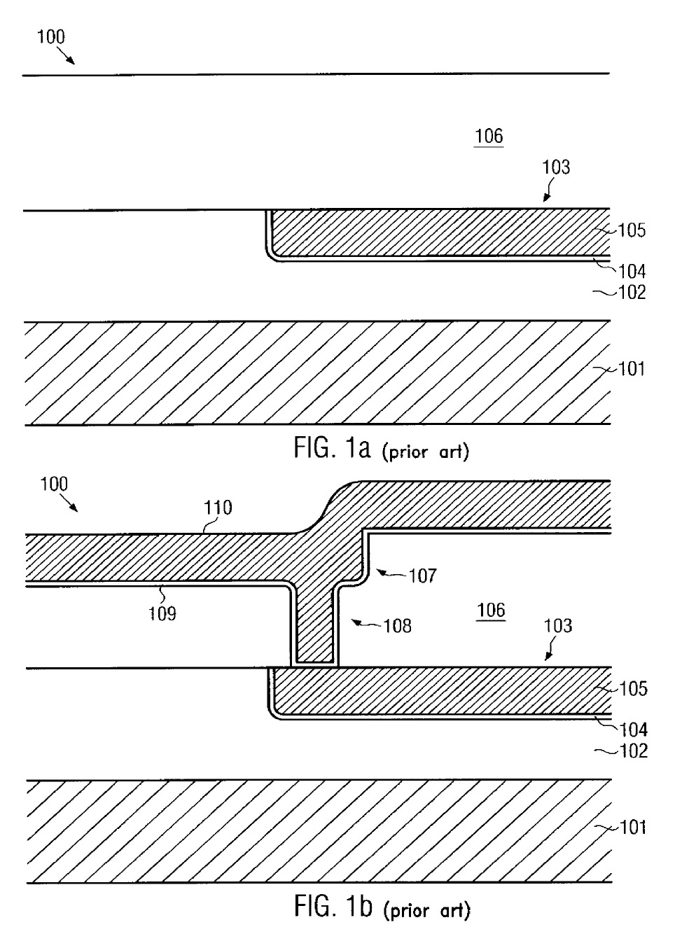

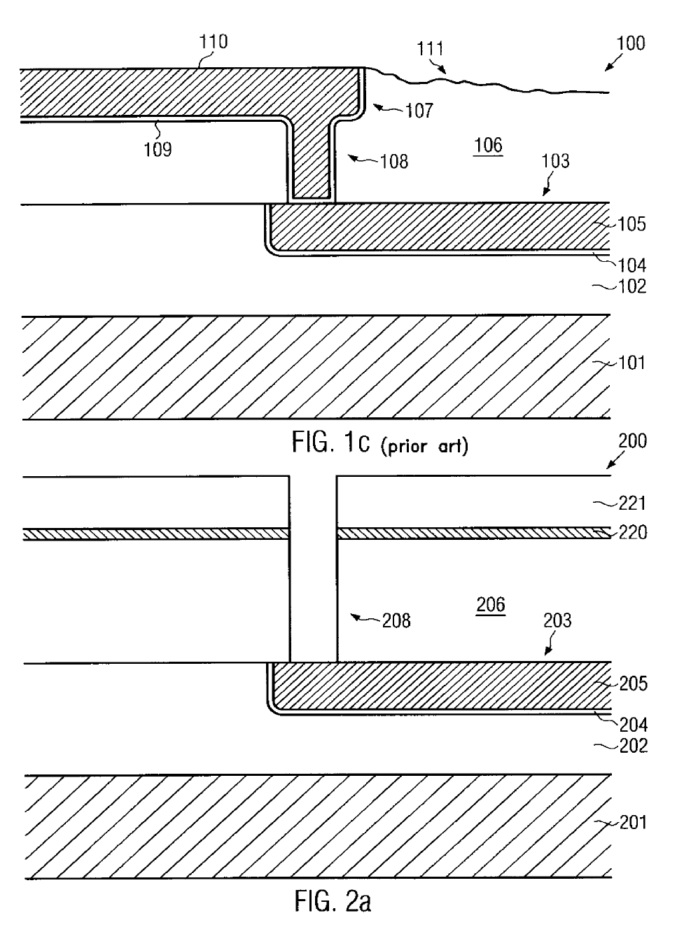

The semiconductor structure 200 comprises a semiconductor substrate 201. In some embodiments, the substrate 201 may comprise silicon. Additionally, the substrate 201 may comprise circuit elements, such as transistors, resistors and/or capacitors (not shown). The substrate 201 may further comprise a layer 202 of an interlayer dielectric, wherein a trench 203 filled with a diffusion barrier layer 204 and a trench fill 205 is formed. Similar to the method of forming a semiconductor structure according to the state of the art described above with respect to FIGS. 1a-1c, the layer 202, the trench 203, the diffusion barrier layer 204 and the trench fill 205 may be formed by means of known methods of photolithography, etching, deposition and planarization.

In some embodiments, the layer 202 of interlayer dielectric may comprise an ultra low-k material, for example, an organo-silicate glass such as silicon oxycarbide, carbon doped oxide or diethoxymethylsilane or a spin-on glass such as methyl silsesquioxane. The trench fill 205 may, in some embodiments, comprise copper. Thus, the trench fill 205 provides an electrically conductive line which may provide electrical connection between circuit elements in the substrate 201. In such embodiments, the diffusion barrier layer 204 may comprise tantalum and/or tantalum nitride to prevent a diffusion of copper from the trench fill 205 into the layer 202 and/or the substrate 201, which might adversely affect the functionality of circuit elements in the substrate 201.

A layer 206 of a first material may be formed over the semiconductor structure 200. The layer 206 may comprise a dielectric material, for example, an ultra low-k material, and may be formed by means of deposition techniques well known to persons skilled in the art, such as spin-on coating, chemical vapor deposition and/or plasma enhanced chemical vapor deposition. The present invention, however, is not restricted to embodiments wherein the first material comprises an ultra low-k material. In other embodiments, the first material may comprise another dielectric material, for example, silicon dioxide, silicon nitride and/or silicon oxynitride.

A protection layer 220 may be formed over the layer 206 of first material. The protection layer 220 may comprise a material having a greater stability under the specific conditions of a chemical mechanical polishing process than the material of the layer 206. In some embodiments, the material of the protection layer 220 may have a greater hardness and/or a greater modulus of elasticity than the material of the first layer 206. In other embodiments, the protection layer 220 may have a lower rate of removal during chemical mechanical polishing or better wetting properties with respect to a slurry used in the chemical mechanical polishing process than the material of the layer 206. In further embodiments, the protection layer 220 may be adapted to protect the semiconductor structure 201 during a plasma resist strip process and/or may be configured to prevent a diffusion of moisture into the layer 206, in particular during a chemical mechanical polishing process wherein the semiconductor structure 200 is exposed to a slurry comprising water. In still further embodiments, the protection layer 220 may be adapted to provide a plurality of the above-mentioned functions. In some embodiments, the protection layer 220 may comprise silicon dioxide, silicon nitride, silicon oxynitride and/or silicon oxycarbide.

After the formation of the protection layer, a contact via 208 may be formed in the layer 206 of the first material. For this purpose, a mask 221, which may comprise a photo-resist of a type well known to persons skilled in the art, may be formed over the protection layer 220. The formation of the mask 221 may be performed by means of techniques of photolithography well known to persons skilled in the art. The mask 221 may cover the protection layer 220 and the layer 206 of the first material with the exception of a location at which the contact via 208 is to be formed.

After the formation of the mask 221, an etch process may be performed. The etch process may be an anisotropic etch process. Advantageously, this may help to obtain substantially vertical sidewalls of the contact via 208. In the etch process, the semiconductor structure 200 may be exposed to an etchant adapted to selectively remove the materials of the protection layer 220 and the layer 206, leaving the trench fill 205 substantially intact. Thus, the etch process stops as soon as the contact via 208 has reached the bottom of the layer 206. After the formation of the contact via 208, the mask 221 may be removed by means of a resist strip process known to persons skilled in the art.

The present invention is not restricted to embodiments wherein a single etch process is used to remove the materials of the protection layer 220 and the layer 206. In other embodiments, a first etch process adapted to selectively remove the material of the protection layer 220 and a second etch process adapted to selectively remove the material of the layer 206 may be employed. In some of these embodiments, the mask 221 may be removed after the first etch process. In the second etch process, the protection layer 220 may then be used as a hard mask.

FIG. 2b shows a schematic cross-sectional view of the semiconductor structure 200 in a later stage of the manufacturing process. After the formation of the contact via 208, a trench 207 may be formed in the layer 206 of first material. Similar to the formation of the contact via 208, this may be done by photolithographically forming a mask 222 over the semiconductor structure 200 which covers the protection layer 220 and the layer 206 with the exception of those portions wherein the trench 207 is to be formed, and then performing an etch process adapted to selectively remove the materials of the protection layer 220 and the layer 206. Thereafter, the mask 222 may be removed by means of a known resist strip process. In other embodiments, two different etch processes may be employed to remove the materials of the protection layer 220 and the layer 206, respectively. In some of these embodiments, the mask 222 may be removed after the etching of the protection layer 220.

FIG. 2c shows a schematic cross-sectional view of the semiconductor structure 200 in a later stage of the manufacturing process. A diffusion barrier layer 209 and a layer 210 of a second material may be formed over the semiconductor structure 200. In some embodiments, the second material may comprise an electrically conductive material, such as copper. In such embodiments, the diffusion barrier layer 209 may be adapted to substantially prevent a diffusion of copper through the diffusion barrier layer 209. In some embodiments, the diffusion barrier layer 209 may comprise tantalum and/or tantalum nitride.

The diffusion barrier layer 209 may be formed by means of deposition techniques well known to persons skilled in the art, such as chemical vapor deposition and/or plasma enhanced chemical vapor deposition. In the formation of the layer 210 of the second material, electroplating techniques may be employed. To this end, a seed layer (not shown) comprising the second material may be formed over the semiconductor structure 200 by means of sputtering and/or electroless deposition. Thereafter, the semiconductor structure 200 may be inserted into an electrolyte comprising ions of the second material. In embodiments wherein the layer 210 comprises copper, the electrolyte may comprise an aqueous solution of a copper salt. An electric voltage may then be applied between the semiconductor structure 200 and an electrode comprising the second material, for example, a copper electrode. A polarity of the voltage is such that, at least on average, the semiconductor structure 200 becomes a cathode and the electrode becomes an anode. Thus, on the surface of the semiconductor structure 200, ions of the second material from the electrolyte are reduced to form the layer 210. At the electrode, the second material is oxidized to form ions which are dissolved in the electrolyte.

FIG. 2d shows a schematic cross-sectional view of the semiconductor structure 200 in a later stage of the manufacturing. After the deposition of the diffusion barrier layer 209 and the layer 210 of the second material, a planarization process may be performed to remove portions of the layer 210 and the diffusion barrier layer 209 outside the trench 207 and the contact via 208. For this purpose, a chemical mechanical polishing process well known to persons skilled in the art may be employed wherein the semiconductor structure 200 is moved relative to a polishing pad and a slurry is supplied to an interface between the semiconductor structure 200 and the polishing pad.

In the chemical mechanical polishing process, the slurry and the polishing pad may contact the layer 210 of the second material, the diffusion barrier layer 209 and, after a removal of portions of the diffusion barrier layer 209 and the layer 210 of the second material, the protection layer 220.

The protection layer 220 may be configured to substantially prevent a contact between the layer 206 of the first material and the slurry as well as a contact between the polishing pad and the layer 206. The chemical mechanical polishing process may be stopped prior to a complete removal of the protection layer 220. In some embodiments, the chemical mechanical polishing process may be stopped as soon as the diffusion barrier layer 209 and the layer 210 are removed and the protection layer 220 is exposed at the surface of the semiconductor structure 300. In such embodiments, the chemical mechanical polishing process may be stopped by means of techniques of endpoint detection well known to persons skilled in the art. In other embodiments, a part of the protection layer 220 may be polished away. Thus, the protection layer 220 may protect the layer 206 of the first material during the whole chemical mechanical polishing process. In such embodiments, the chemical mechanical polishing process may be stopped after the expiry of a predetermined polishing time.

Hence, mechanical damages of the layer 206 of the first material occurring during the chemical mechanical polishing process may be substantially avoided. Additionally, the protection layer 220 may improve the rate of material removal during the chemical mechanical polishing process, may improve a wetting of the semiconductor structure 200 during the chemical mechanical polishing process, and may provide a barrier preventing an intrusion of moisture, e.g., from the slurry, into the layer 206 during the chemical mechanical polishing process as well as during other processing steps. Furthermore, the protection layer 220 may protect the layer 206 from being affected by resist strip processes, for example during resist strip processes employed for the removal of the masks 221, 222.

The second material of the layer 210 which remains in the trench 207 and the contact via 208 after the planarization process may form an electrically conductive feature provided in form of an electrically conductive line, wherein the material in the contact via 208 provides an electrical connection to the electrically conductive line provided by the trench fill 205 in the trench 203.

FIG. 2e shows a schematic cross-sectional view of the semiconductor structure 200 in a later stage of the method. After the planarization process, the portions of the protection layer 220 which were not removed during the planarization process may be removed. For this purpose, an etch process may be performed. An etchant employed in the etch process may be adapted to selectively remove the material of the protection layer 220, leaving the diffusion barrier layer 209, the second material of the layer 210 and the first material of the layer 206 substantially intact. In some embodiments, the etch process may be a dry etch process. In other embodiments, a wet etch process may be performed.

Advantageously, removing the protection layer 220 after the planarization process may help reduce RC propagation delays which might occur during the operation of the semiconductor structure 200. Since the protection layer 220 may have a greater dielectric constant than the first material 206, in particular in embodiments wherein the layer 206 comprises an ultra low-k material, the removal of the protection layer 220 may help lowering the effective dielectric constant in the vicinity of the electrically conductive line provided by the second material in the trench 207 and the contact via 208. Thus, a capacity between the electrically conductive line and other electrically conductive features in the semiconductor structure 200 may be advantageously reduced, which may help reduce RC propagation delays.

In some embodiments, after the removal of the protection layer 220, manufacturing steps similar to those described above with reference to FIGS. 2a-2e may be performed in order to form a further, higher interconnect level of the semiconductor structure 200.

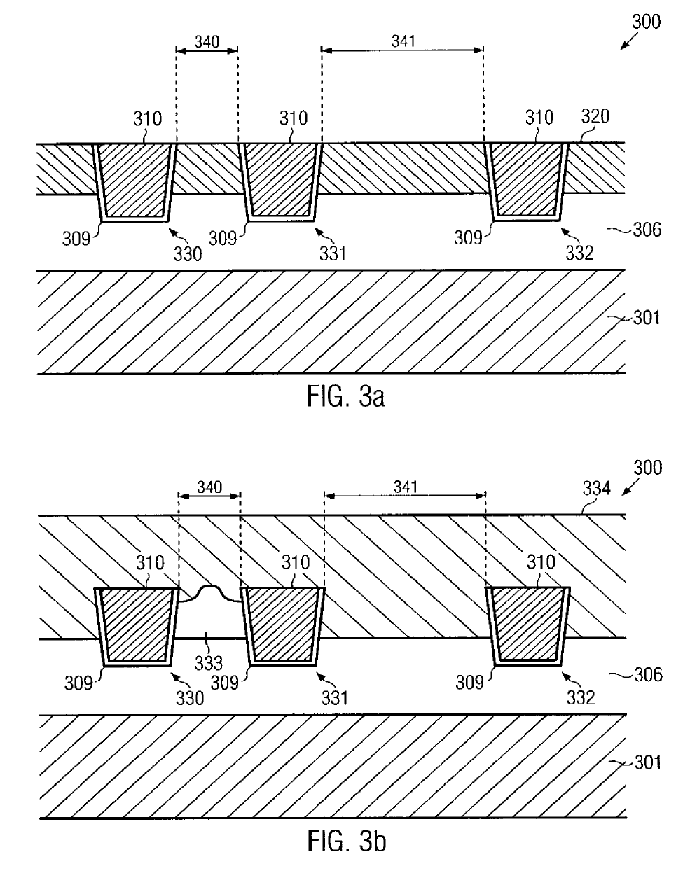

FIG. 3a shows a schematic cross-sectional view of a semiconductor structure 300 in a first stage of a method of forming a semiconductor structure. The semiconductor structure 300 comprises a semiconductor substrate 301 which may, in some embodiments, comprise silicon. Additionally, the semiconductor substrate 301 may comprise circuit elements such as transistors, capacitors and resistors, as well as electrically conductive lines in lower interconnect levels providing electrical connection between the circuit elements (not shown).

A layer 306 of a first material may be formed on the substrate 301. Similar to the layer 206 in the semiconductor structure 200 described above with reference to FIGS. 2a-2e, the layer 306 may comprise an ultra low-k material having a dielectric constant of about 2.4 or less, for example an organo-silicate glass such as hydrogenated silicon oxycarbide, carbon doped oxide or diethoxymethylsilane, or a spin-on glass such as methyl silsesquioxane. In other embodiments, the layer 306 may comprise a dielectric material having a dielectric constant greater than 2.4, for example, silicon dioxide, silicon nitride and/or silicon oxynitride.

The semiconductor structure 300 may further comprise a protection layer 320. Similar to the protection layer 220 employed in the formation of the semiconductor structure 200 described above with reference to FIGS. 2a-2e, the protection layer 320 may comprise a material having a greater stability than the material of the layer 306. Additionally, the protection layer 320 may be configured to improve a rate of material removal and/or wetting properties of the semiconductor structure 300 during a chemical mechanical polishing process and to protect the layer 306 from being affected by a plasma resist strip employed in photolithographic processes used in the formation of the semiconductor structure 300, and may provide a moisture barrier configured to prevent an intrusion of moisture into the layer 306 comprising the first material.

Additionally, the semiconductor structure 300 may comprise a first trench 330, a second trench 331 and a third trench 332. A distance 340 between the first trench 330 and the second trench 331 may be greater than a distance between the second trench 331 and the third trench 332. In the trenches 330, 331, 332, a diffusion barrier layer 309 and a layer 310 of a second material are provided. Similar to the layer 210 of second material and the diffusion barrier layer 209 in the semiconductor structure 200 described above with reference to FIGS. 2a-2e, the layer 310 of second material may comprise copper and the diffusion barrier layer 309 may be configured to substantially prevent a diffusion of copper thorough the diffusion barrier layer 309.

The protection layer 320 may have a thickness adapted such that a significant portion of the trenches 330, 331, 332 is provided in the protection layer 320. In some embodiments, the thickness of the protection layer 320 may be greater than about one quarter of the depth of the trenches 330, 331, 332. In other embodiments, the thickness of the protection layer 320 may be greater than about one third of the depth of the trenches 330, 331, 332, greater than about one half of the depth of the trenches 330, 331, 332, or even greater than about two thirds of the depth of the trenches 330,331, 332.

The semiconductor structure 300 may be formed by means of techniques of photolithography, etching, deposition and planarization, similar to the formation of the semiconductor structure 200 described above with reference to FIGS. 2a-2e.

FIG. 3b shows a schematic cross-sectional view of the semiconductor structure 300 in a later stage of the manufacturing process. After the completion of the formation of the trenches 330, 331, 332, the protection layer 320 may be removed. For this purpose, an etch process adapted to selectively remove the material of the protection layer 320, leaving the materials of the layer 306 of first material, the diffusion barrier layer and the layer 310 of second material substantially intact, may be employed. While, in some embodiments, the etch process may be a wet etch process, in other embodiments, a dry etch process may be employed.

After the removal of the protection layer 320, portions of the diffusion barrier layer 309 and the layer 310 of the second material which were located in portions of the trenches 330, 331, 332 located in the protection layer 320 protrude out of the layer 306 of first material and form protrusions located over the trenches 330, 331, 332.

Subsequently, a layer 334 of a third material may be formed over the semiconductor structure 300. The layer 334 of third material may, in some embodiments, comprise an ultra low-k material having a dielectric constant less than about 2.4. In other embodiments, the layer 334 of third material can comprise a dielectric material having a dielectric constant greater than about 2.4, for example, silicon dioxide, silicon nitride and/or silicon oxynitride.

In the formation of the layer 334 of third material, a deposition process comprising spin-on deposition, chemical vapor deposition and/or plasma enhanced chemical vapor deposition may be performed. The deposition process may be configured to form a void 333 between the first trench 330 and the second trench 331. In some embodiments, the deposition process may further be adapted such that substantially no void is formed between the second trench 331 and the third trench 332 having a distance 341 being greater than a distance 340 between the first trench 330 and the second trench 331.

As persons skilled in the art know, in spin-on deposition, the semiconductor structure 200 may be rotated. Thereafter, a solution of the third material in a solvent may be supplied to the center of rotation of the semiconductor structure 300. Thus, the solution is distributed over the surface of the semiconductor structure 300 by centrifugal forces. The solvent is then evaporated, for example, by heating the semiconductor structure 300. Thereby, the third material remains on the surface of the semiconductor structure 300 to form the layer 334 of the third material.

The formation of the void 333 may be controlled by adapting the surface tension of the solution of the third material. In case a relatively high surface tension of the solution is provided, the surface tension may prevent the solvent from entering a region between the protrusions formed over the first trench 330 and the second trench 331. Thus, the void 333 may be formed between the first trench 330 and the second trench 331.

In embodiments wherein the distance 341 between the second trench 301 and the third trench 306 is greater than the distance 340 between the first trench 300 and the second trench 301, solvent may enter the room between the second trench 331 and the third trench 332. Thus, the void 333 may be selectively formed between the first trench 330 and the second trench 331.

In chemical vapor deposition, the semiconductor structure 300 is placed inside a reactor vessel, and reactant gases well known to persons skilled in the art are supplied to the reactor vessel. The reactant gases are adapted to react chemically on the surface of the semiconductor structure 300 or in the vicinity thereof. In the chemical reaction, the third material is formed. The third material is deposited on the semiconductor structure 300 to form the layer 334 of the second material. Other products of the chemical reactions and unconsumed reactants may be flown out of the reactor vessel.

Plasma enhanced chemical vapor deposition is a variant of chemical vapor deposition wherein an electric glow discharge is created in the reactant gas by applying a radio frequency alternating voltage to the reactant gas. Additionally, a bias voltage which may be a direct voltage or a low-frequency alternating voltage may be applied between the semiconductor structure 300 and an electrode provided in the reactant gas. Advantageously, creating the glow discharge in the reactant gas allows performing the deposition process at a lower temperature than in a plasma-less chemical vapor deposition. The bias voltage may be varied to control a degree of isotropy of the deposition process. In general, a low bias voltage or no bias voltage at all may help to obtain a substantially conformal deposition of the third material.

In embodiments wherein the layer 334 of the third material is formed by means of chemical vapor deposition and/or plasma enhanced chemical vapor deposition, the formation of the void 333 between the first trench 330 and the second trench 331 may be controlled by varying the composition, the pressure and the temperature of the reactant gas, and/or other parameters of the deposition process. In embodiments wherein plasma enhanced chemical vapor deposition is performed, the amplitude and/or the frequency of the radio frequency alternating voltage as well as the amplitude and/or frequency of the bias voltage may also be varied.

The parameters of the chemical vapor deposition process or the plasma enhanced chemical vapor deposition process, respectively, may be adapted such that material transport into narrow openings, such as the region between the first trench 330 and the second trench 331, is limited. Parameter values adapted for this purpose are known to persons skilled in the art or may readily be determined by means of routine experimentation. Thus, on portions of the surface of the layer 306 of first material between the trenches 330, 331, only a small amount of material is deposited, whereas a relatively quick material deposition may occur on top surfaces of the protrusions formed over the trenches 330, 331. The material deposited on the top surfaces may then overgrow the region between the trenches 330, 331 to form the void 333.

Since the second trench 331 and the third trench 332 are provided at a distance 341 which is greater than the distance 340 between the first trench 330 and the second trench 331, material transport to portions of the surface of the layer 306 of first material between the second trench 331 and the third trench 332 may be less limited than the transport of material to the region between the first trench 330 and the second trench 331. Thus, a formation of a void between the second trench 331 and the third trench 331 may be avoided.

Hence, the subject matter disclosed herein may allow the selective formation of voids between narrowly spaced trenches, wherein a formation of voids between trenches provided at a greater distance may be avoided. The presence of the voids between the trenches may allow a reduction of signal propagation delays, since the voids may have a dielectric constant of about 1, which may be significantly smaller than the dielectric constants of current ultra low-k dielectrics. Since there can be a greater capacity between narrowly spaced trenches than between trenches provided at a greater distance to each other, and a greater capacity may lead to an increased RC propagation delay, the subject matter disclosed herein may advantageously allow reducing the RC propagation delay in those portions of the semiconductor structure 300 wherein a particularly large RC propagation delay may occur. The absence of voids in portions of the semiconductor structure 300 comprising trenches provided at a moderately large distance to each other may help increase the mechanical stability of the semiconductor structure 300.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1-8. (canceled)

9. A method of forming a semiconductor structure, comprising:
forming a protection layer over a layer of a first material formed above a substrate;
forming a first trench and a second trench in said protection layer and said layer of first material, said first trench and said second trench being adjacent each other;
filling said first trench and said second trench with a second material;
performing an etching process to remove said protection layer, said etching process being adapted to leave said second material substantially intact such that a first protrusion comprising said second material is formed over said first trench and a second protrusion comprising said second material is formed over said second trench; and
performing a deposition process to form a layer of a third material over said substrate, wherein said deposition process is adapted to form a void between said first protrusion and said second protrusion.

10. The method of forming a semiconductor structure as in claim 9, wherein said first material comprises a dielectric material.

11. The method of forming a semiconductor structure as in claim 10, wherein a dielectric constant of said first material is smaller than about 2.4.

12. The method of forming a semiconductor structure as in claim 9, wherein said first material comprises at least one of an organo-silicate glass and a spin-on glass.

13. The method of forming a semiconductor structure as in claim 9, wherein said protection layer comprises a material being harder than said first material.

14. The method of forming a semiconductor structure as in claim 9, wherein said protection layer comprises at least one of silicon dioxide, silicon nitride and/or silicon oxynitride.

15. The method of forming a semiconductor structure as in claim 9, wherein said second material comprises copper.

16. The method of forming a semiconductor structure as in claim 9, wherein said deposition process comprises at least one of chemical vapor deposition, plasma enhanced chemical vapor deposition and spin-on coating.

17.-20. (canceled)
